(19) United States
(12) Patent Application Publication
(10) Pub. No.: US 2013/0250271 A1
(43) Pub. Date: Sep. 26, 2013

(54) STAGE ASSEMBLY WITH SECURE DEVICE HOLDER

(71) Applicant: NIKON CORPORATION, Tokyo (JP)

(72) Inventors: Alton H. Phillips, East Palo Alto, CA (US); Fardad Hashemi, Moraga, CA (US); Takeshi Matsuda, Saitama-shi (JP)

(73) Assignee: NIKON CORPORATION, Tokyo (JP)

(21) Appl. No.: 13/768,211

(22) Filed: Feb. 15, 2013

Related U.S. Application Data
(60) Provisional application No. 61/600,351, filed on Feb. 17, 2012.

(51) Int. Cl. G03F 7/20

(52) U.S. Cl. CPC G03F 7/70725
USPC 355/73

(57) ABSTRACT

A stage assembly (10) that moves a device (22) includes a device holder (20) that selectively retains the device (22). The device holder (20) includes a pivot (330) that engages the device (22), and a pressure source (326) that creates (i) a pressure controlled, distal zone (336A) that is at a distal pressure, and (ii) a pressure controlled, proximal zone (338A) that is at a proximal pressure. The distal zone (336A) generates a distal moment (344A) and the proximal zone (336B) generates a proximal moment (346A) that can be used to control the shape of the device (22).

### RELATED INVENTION

This application claims priority on U.S. Provisional Application Ser. No. 61/600,351, filed Feb. 17, 2012 and entitled “STAGE ASSEMBLY WITH SECURE DEVICE HOLDER”. As far as permitted, the contents of U.S. Provisional Application Ser. No. 61/600,351 are incorporated herein by reference.

### BACKGROUND

Exposure apparatuses for semiconductor processing are commonly used to transfer images from a reticle onto a semiconductor wafer during semiconductor processing. A typical exposure apparatus includes an illumination source that directs light energy at the reticle, a reticle stage assembly that holds and positions a reticle, an optical assembly, a wafer stage assembly that holds and positions a semiconductor wafer, a measurement system, and a control system.

One type of reticle stage assembly includes a stage having a device holder that retains the reticle, and a stage mover assembly that moves the stage. The light directed at the reticle can cause thermal distortions to the reticle. Thus, it is often desired to bend the reticle to correct for the thermal distortions.

One type of device holder is a vacuum type chuck that uses a vacuum to pull the device against the stage. Unfortunately, existing chucks do not accurately bend the reticle and/or do not have a sufficient bending range.

### SUMMARY

The present invention is directed a stage assembly that moves a device positioned in an environment that is at an environmental pressure. The stage assembly includes a stage housing and a device holder. The device holder selectively secures the device to the stage housing. In one embodiment, the device holder includes a first holder that defines a first pivot that engages the device, and a pressure source that is in fluid communication with the first holder. The pressure source creates (i) a pressure controlled, first distal zone between the first holder and device that is at a first distal pressure, and (ii) a pressure controlled, first proximal zone between the first holder and device that is at a first proximal pressure. The first proximal zone is closer to a predetermined axis (e.g. a center or central axis) of the device than the first distal zone. In certain embodiments, (i) at least one of the first pressures is less than the environmental pressure, (ii) the first distal pressure in the first distal zone generates a first distal moment on the device near the first pivot, and (iii) the first proximal pressure in the first proximal zone generates a first proximal moment on the device near the first pivot.

With this design, the device holder accurately and securely retains and holds a device with a relatively high holding force. Further, the device holder can be used to accurately bend the device, the device holder has a relatively large bending range, and the device holder can perform higher-order bending. Moreover, the device holder maximizes first and second order stroke without significantly sacrificing the holding force.

In one embodiment, the pressure source controls each of the first pressures to be are less than the environmental pressure. In this embodiment, the first distal moment is substantially opposite in direction to the first proximal moment. Alternatively, the pressure source can control one of the first pressures to be greater than the environmental pressure. In this embodiment, the first distal moment is substantially in the same direction as the first proximal moment. In each of these embodiments, the pressure source can control the first pressures to control the shape of the device.

In one embodiment, the first pivot is positioned in the first distal zone. Alternatively, the first pivot can be positioned intermediate the first distal zone and the first proximal zone.

In certain embodiments, the first pivot provides an area of approximate line contact with the device.

Additionally, the device holder can includes a second holder that is spaced apart from the first holder, the second holder defining a second pivot that also engages the device. In this embodiment, the pressure source is in fluid communication with the second holder to provide (i) a pressure controlled, second distal zone between the second holder and device that is at a second distal pressure, and (ii) a pressure controlled, second proximal zone between the second holder and device that is at a second proximal pressure. Further, in this embodiment, (i) the second proximal zone is closer to the central axis than the second distal zone, (ii) at least one of the second pressures is less than the environmental pressure, (iii) the second distal pressure in the second distal zone generates a second distal moment on the device near the second pivot, and (iv) the second proximal pressure in the second proximal zone generates a second proximal moment on the device near the second pivot.

Moreover, in certain embodiments, the device is retained a relatively small fluid gap away from the first holder so that the device experiences squeeze film damping.

The present invention is also directed to an exposure apparatus including the stage assembly retaining the device, and an illumination system that directs an energy beam at the device. Further, the present invention is also directed to a wafer, and a method for manufacturing an object or a wafer.

In yet another embodiment, the present invention is directed to a method for retaining a device including the steps of (i) positioning the device on a first pivot of a first holder; (ii) generating a first distal moment on the device near the first pivot by creating a pressure controlled, first distal zone between the first holder and the device that is at a first distal pressure; and (iii) generating a first proximal moment on the device near the first pivot by creating a pressure controlled, first proximal zone between the first holder and the device that is at a first proximal pressure.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a simplified side view of a stage mover assembly having features of the present invention retaining a device;

FIG. 2 is a simplified cut-away view of a portion of the device and a device holder having features of the present invention;

FIG. 3A is a perspective view of a holder having features of the present invention;

FIG. 3B is a top view of the holder of FIG. 3A;

FIG. 3C is a perspective view of a portion of the holder of FIG. 3A;

FIG. 3D is a top view of a portion of the holder of FIG. 3A;

FIG. 3E is a perspective cut-away view of a portion of the holder of FIG. 3C;

FIG. 3F is a cut-away view of the holder of FIG. 3C;

FIG. 4 is a simplified cut-away view of a portion of the device and another embodiment of a device holder having features of the present invention;

FIG. 5 is a simplified cut-away view of a portion of the device and still another embodiment of a device holder having features of the present invention;

FIG. 6A is a simplified cut-away view of a portion of the device and yet another embodiment of a device holder having features of the present invention in an unlocked position;

FIG. 6B is a simplified cut-away view of a portion of the device and the device holder of FIG. 6A in a locked position;

FIG. 7 is a top view of another embodiment of a holder having features of the present invention.

FIG. 8 is a simplified perspective view of one embodiment of a pivot having features of the present invention;

FIG. 9 is a simplified perspective view of another embodiment of a pivot having features of the present invention;

FIG. 10A is a simplified partially cut away view of a device and another embodiment of a holder having features of the present invention;

FIG. 10B is a simplified cut away view taken on line 10B-10B in FIG. 10A;

FIG. 10C is a simplified cut away view taken on line 10C-10C in FIG. 10A illustrating the holder bending the device in a concave fashion;

FIG. 10D is still another alternative cut away view of FIG. 10C, with the holder bending the device in a convex fashion;

FIG. 10E is a more detailed, perspective view of the holder of FIG. 10A;

FIG. 10F is an exploded perspective view of the holder of FIG. 10E;

FIG. 11 is a simplified illustration of an exposure apparatus having features of the present invention;

FIG. 12A is a flow chart that outlines a process for manufacturing a device in accordance with the present invention; and

FIG. 12B is a flow chart that outlines device processing in more detail.

### DESCRIPTION

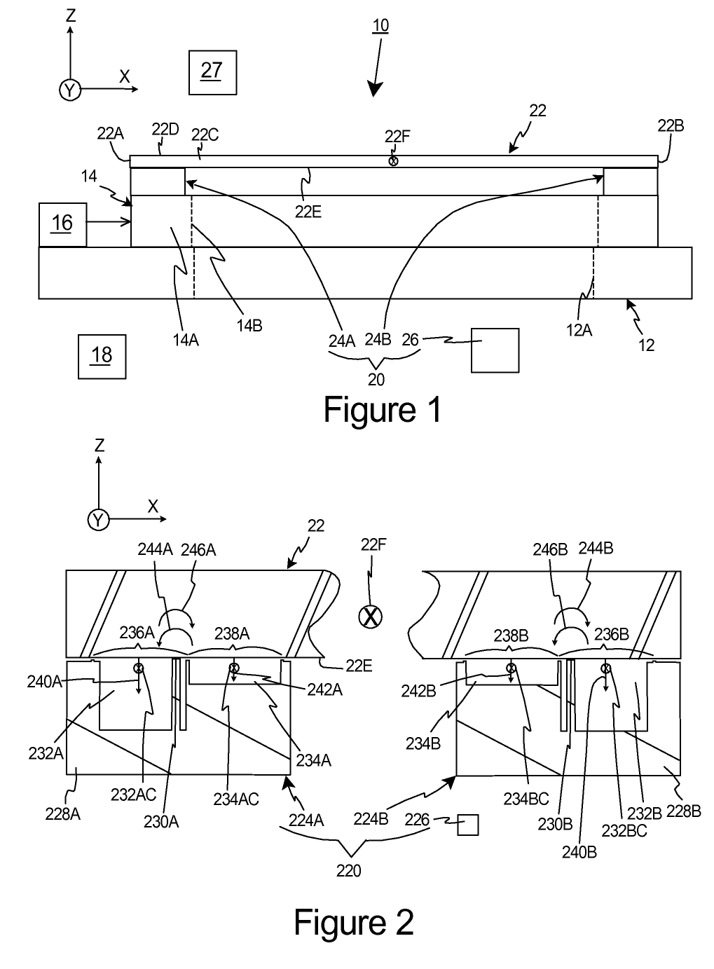

Referring initially to FIG. 1, a stage assembly 10 having features of the present invention includes a stage base 12, a stage 14, a stage mover 16 (illustrated as a box), and a control system 18. The design of each of these components can be varied to suit the design requirements of the assembly 10. As an overview, the stage 14 includes a device holder 20 that accurately and securely retains and holds a device 22 with a relatively high holding force. Further, in certain embodiments, the device holder 20 accurately bends the device 22, has a relatively large bending range, relatively high pitching stiffness, relatively high dynamic modes, and is relatively easy to expand for higher-order bending. Moreover, the device holder 20 maximizes first and second order stroke without significantly sacrificing holding force. Additionally, the device holder 20 is a relatively simple mechanism to manufacture and assemble.

The stage assembly 10 is particularly useful for precisely positioning the device 22 during a manufacturing, a measuring and/or an inspection process. The type of device 22 positioned and moved by the stage assembly 10 can be varied. For example, the device 22 can be a reticle, and the stage assembly 10 can be used as part of an exposure apparatus for manufacturing of a semiconductor wafer. The reticle can be transmissive or reflective.

Alternately, for example, the stage assembly 10 can be used to move other types of devices during manufacturing and/or inspection, to move a device under an electron microscope (not shown), or to move a device during a precision measurement operation.

In the embodiment illustrated in FIG. 1, the device 22 is generally rectangular shaped and includes (i) four sides, namely a left first side 22A, a right second side 22B that is spaced apart from the left first side 22A, a front side 22C and a rear side (not visible in FIG. 1); (ii) a top 22D; (iii) a bottom 22E, and (iv) a predetermined axis 22F (illustrated as a circle with an X) between the first side 22A and the second side 22B. Alternatively, the device 22 can have another configuration. In certain embodiments, the predetermined axis 22F is a center axis.

Some of the Figures provided herein include an orientation system that designates an X axis, a Y axis, and a Z axis. It should be understood that the orientation system is merely for reference and can be varied. For example, the X axis can be switched with the Y axis and/or the stage assembly 10 can be rotated. Moreover, these axes can alternatively be referred to as a first, second, or third axis.

In the embodiments illustrated herein, the stage assembly 10 includes a single stage 14 that is moved relative to the stage base 12. Alternately, for example, the stage assembly 10 can be designed to include multiple stages that are independently moved relative to the stage base 12.

The stage base 12 supports a portion of the stage assembly 10. In FIG. 1, the stage base 12 is generally rectangular shaped. In certain embodiments, the stage base 12 can include a base aperture 12A (illustrated in phantom) that allows light to pass therethrough. For example, the base aperture 12A can be a generally rectangular shaped opening.

The stage 14 retains the device 22. The stage 14 is precisely moved by the stage mover 16 to precisely position the device 22. In certain embodiments, the stage 14 includes a rigid stage housing 14A that can have a stage aperture 14B (illustrated in phantom) that allows light to pass therethrough. For example, the stage housing 14A can be generally rectangular shaped, and the stage aperture 14BA can be a generally rectangular shaped opening.

Additionally, the stage 14 includes the device holder 20 that securely retains the device 22. In one embodiment, the device holder 20 includes (i) a left, first holder 24A, (ii) a right, second holder 24B is that spaced apart from the first holder 24A, and (iii) a pressure source 26 that is in fluid communication with the holders 24A, 24B. In one embodiment, the pressure source 26 supplies a controlled pressurized fluid and/or a controlled vacuum to the holders 24A, 24B so that the holders 24A, 24B cooperate to retain the device 22. The design of these components can vary pursuant to the teachings provided herein.

In FIG. 1, the first holder 24A retains the device 22 near the first side 22A, and the second holder 24B retains the device 22 near the second side 22B. With the present design, the holders 24A, 24B can be individually adjusted via the pressure source 26 to precisely adjust the holding force and bending of the device 22.

It should be noted that the stage housing 14A and the holders 24A, 24B can be made as a one piece, monolithic structure. Alternatively, the holders 24A, 24B and the stage housing 14A can be made from separate structures, and the holders 24A, 24B can be fixedly secured to the stage housing 14A.

The stage mover 16 moves and positions the stage 14 relative to the stage base 12. For example, the stage mover 16 can move the stage 14 along the X, Y and Z axes, and about the X, Y and Z axes (six degrees of freedom). Alternatively, the stage mover 16 can move the stage with fewer than six degrees of freedom.

The control system 18 is electrically connected to and directs and controls electrical current to the stage mover 16 to precisely position the device 22. Further, the control system 18 is electrically connected to and controls the device holder 20 to control the holding force and selectively apply bending moments on the device 22 to control the shape of the device 22. The control system 18 can include one or more processors.

As non-exclusive examples, the bending moments selectively applied to the device 22 can be used (i) to lessen or counteract the effects of gravity on the device 22, (ii) to counteract the influence of thermal gradients on the device 22, (iii) to correct a deformed device 22, (iv) to counteract thermal distortion in other components, such as the lens of the projection optical assembly, (v) to correct for other errors that occur in the exposure process such as positioning errors, and/or (v) to provide another adjustment to the exposure apparatus. As provided herein, the device 22 can be selectively distorted to achieve substantial flatness of the device 22, and/or to create the shape of the device 22 that is necessary to achieve the desired pattern transfer.

In certain embodiments, the control system 18 includes a feedback system 27 (illustrated as a box) that provides feedback regarding one or more characteristics of the device 22. For example, the feedback system 27 can include an auto-focus system that constantly or intermittently monitors shape of the device 22. With this design, the control system 18 can utilize the feedback to control the pressure source 26 to adjust the shape of the device 22 to achieve the desired shape. Alternatively or additionally, the feedback system 27 can include one or more temperature sensors that monitor the temperature at one or more locations on the device 22.

Additionally or alternatively, the control system 18 can include a simulated model of the device 22 that simulates the conditions in which the device 22 is being exposed. Using information from the model, the control system 18 can control the pressure source 26 to apply the appropriate moments on the device 22 to achieve the desired shaped of the device 22.

It should be noted that the stage assembly 10 and the device 22 are positioned in an environment that is at an environmental pressure. Typically, the stage assembly 10 is operated in an environment that is at atmospheric pressure. Alternatively, the environmental pressure can be greater than or less than atmospheric pressure.

FIG. 2 is a simplified cut-away view of a portion of the device 22, and a first embodiment of the device holder 220 including the first holder 224A, the second holder 224B, and the pressure source 226. In this embodiment, the first holder 224A includes a first holder housing 228A that defines (i) a first pivot 230A that engages the bottom 22E of the device 22; (ii) a first distal region 232A adjacent the bottom 22E of the device 22; and (iii) a first proximal region 234A adjacent the bottom 22E of the device 22. Similarly, the second holder 224B includes a second holder housing 228B that defines (i) a second pivot 230B that engages the bottom 22E of the device 22; (ii) a second distal region 232B adjacent the bottom 22E of the device 22; and (iii) a second proximal region 234B adjacent the bottom 22E of the device 22. The first pivot 230A is spaced apart from the second pivot 230B along the X axis.

In one non-exclusive embodiment, each holder housing 228A, 228B is a generally rectangular shaped rigid block. However, each holder housing 228A, 228B can have different shape or configuration than that illustrated in FIG. 2.

In certain embodiments, each pivot 230A, 230B provides an area of approximate line contact (extending along the Y axis) with the bottom 22E of the device 22. The pivots 230A, 230B are spaced apart, so that the device 22 is supported by the two spaced apart line contacts that extend along the Y axis. In one embodiment, each pivot 230A, 230B can be rigid along the Z axis, along the Y axis, about the X axis, and about the Z axis, and compliant along the X axis, and about the Y axis. Each pivot 230A, 230B can also be referred to as a fulcrum.

It should be noted that in FIG. 2, the first pivot 230A is positioned in the first distal region 232A, and the first proximal region 234A is positioned near the first distal region 232A and the first pivot 230A. Further, the first proximal region 234A is closer to the center axis 22F of the device 22 than the first distal region 232A. Similarly, the second pivot 230B is positioned in the second distal region 232B, and the second proximal region 234B is near the second distal region 232B and the second pivot 230B. Further, the second proximal region 234B is closer to the center axis 22F of the device 22 than the second distal region 232B.

Moreover, (i) a center 232AC (illustrated with a circle and an X) of the first distal region 232A near the device 22 is left of first pivot 230A; (ii) a center 234AC (illustrated with a circle and an X) of the first proximal region 234A near the device is right of first pivot 230A; (iii) a center 232BC (illustrated with a circle and an X) of the second distal region 232B near the device is right of second pivot 230B; and (iv) a center 234BC (illustrated with a circle and an X) of the second proximal region 234B near the device is left of second pivot 230B.

In one embodiment, the pressure source 226 controls (i) a first distal pressure in the first distal region 232A to create a pressure controlled, first distal zone 236A between the device 22 and the first holder 224A; (ii) a first proximal pressure in the first proximal region 234A to create a pressure controlled first proximal zone 238A between the device 22 and the first holder 224A; (iii) a second distal pressure in the second distal region 232B to create a pressure controlled, second distal zone 236B between the device 22 and the second holder 224B; and (iv) a second proximal pressure in the second proximal region 234B to create a pressure controlled, second proximal zone 238B between the device 22 and the second holder 224B.

As provided herein, the pressure source 226 can individually control the pressure in each of the regions 232A, 234A, 232B, 234B to be below the environmental pressure or above the environmental pressure as required to achieve the desired shaped of the device 22.

As used herein, the term “negative pressure” shall refer to a gaseous pressure that is less than (below) the environmental pressure, and the term “positive pressure” shall refer to a gaseous pressure that is greater than the environmental pressure. If the environmental pressure is equal to the atmospheric pressure, (i) a negative pressure is less than atmospheric pressure (e.g. a vacuum, or partial vacuum), and (ii) a positive pressure is greater than atmospheric pressure.

In one embodiment, the pressure source 226 can individually control the pressure in each of the regions 232A, 234A, 232B, 234B to be a negative pressure. With this embodiment, the negative pressure (i) in the first distal zone 236A will create a first distal force 240A (illustrated as an arrow) downward on the device 22; (ii) in the first proximal zone 238A will create a first proximal force 242A (illustrated as an arrow) downward on the device 22; (iii) in the second distal zone 236B will create a second distal force 240B (illustrated as an arrow) downward on the device 22; and (iv) in the second proximal zone 238B will create a second proximal force 242B (illustrated as an arrow) downward on the device 22. With this design, the first forces 240A, 242A will pull/urge the device 22 against the first pivot 230A, and the second forces 240B, 242B will pull/urge the device 22 against the second pivot 230B.

It should be noted that although each force 240A, 240B, 242A, 242B is illustrated as a single arrow centered in its respective zone 236A, 236B, 238A, 238B, in reality, each force 240A, 240B, 242A, 242B is actually distributed along the area of its respective zone 236A, 236B, 238A, 238B. In the embodiment illustrated in FIG. 2, (i) the first proximal force 242A and the bulk of the first distal force 240A are positioned on opposite sides of the first pivot 230A; and (ii) the second proximal force 242B and the bulk of the second distal force 240B are positioned on opposite sides of the second pivot 230B.

In one embodiment, the size of each region 232A, 234A, 232B, 234B can be varied and selected to provide the desired range of possible forces 240A, 240B, 242A, 242B at each zone 236A, 236B, 238A, 238B. Further, the pressure in the zone 236A, 236B, 238A, 238B can be individually adjusted to individually adjust each force 240A, 240B, 242A, 242B. Thus, the pressure in each zone 236A, 236B, 238A, 238B can be individually adjusted to adjust the holding force of the device holder 220.

Moreover, as provided herein, the pressure in one or more of the zones 236A, 236B, 238A, 238B can be individually adjusted to adjust the shape of the device 22. As provided herein, (i) because the first pivot 230A is offset (positioned to the right) from center 232AC in the first distal zone 236A, the first distal force 240A will create a first distal moment 244A about (near) the first pivot 230A on the device 22; (ii) the first proximal force 242A will create a first proximal moment 246A about (near) the first pivot 230A on the device 22; (iii) because the second pivot 230B is offset (positioned to the left) from the center 232BC in the second distal zone 236B, the second distal force 240B will create a second distal moment 244B about (near) the second pivot 230B on the device 22; and (iv) the second proximal force 242B will create a second proximal moment 246B about (near) the second pivot 230B on the device 22. With this design, the pressure in each zone 236A, 236B, 238A, 238B can be individually adjusted to individually adjust each force 240A, 240B, 242A, 242B, and individually adjust each moment 244A, 244B, 246A, 246B that is applied to the device 22, and ultimately control the shape of the device 22.

In the example illustrated in FIG. 2, (i) the first distal moment 244A is opposite in direction to the first proximal moment 246A, and (ii) the second distal moment 244B is opposite to the second proximal moment 246B. As viewed in FIG. 2, (i) the first distal moment 244A and the second proximal moment 246B are counterclockwise, and (ii) the second distal moment 244B and the first proximal moment 246A are clockwise.

As a simplified example, if the pressures are controlled so that (i) the first distal moment 244A is greater than the first proximal moment 246A, and (ii) the second distal moment 244B is greater than the second proximal moment 246B, the device 22 is bent in a concave fashion with the center axis 22F being moved upward. In contrast, if the pressures are controlled so that (i) the first distal moment 244A is less than the first proximal moment 246A, and (ii) the second distal moment 244B is less than the second proximal moment 246B, the device 22 is bent in a convex fashion with the center axis 22F being moved downward. Thus, the bending moments 244A, 244B, 246A, 246B generated by the device holder 220 provided herein can be adjusted to move the center axis 22F of the device 22 upward or down. Further, the bending moments 244A, 244B, 246A, 246B can be individually adjusted to change the shape of the device 22 in other, more complicated fashions. Stated in another fashion, the device holder 220 can be used to bend the device in both directions and to apply moments in both directions.

In FIG. 2, each region 232A, 232B, 234A, 234B includes one or more cavities that are subject to the controlled pressure.

With the embodiments disclosed herein, the problem of an overly complex mechanism for holding and bending a device 22 (e.g. a reticle) is solved by a relatively simple device holder 220 that holds and bends the device 22. As provided herein, the device holder 220 including a two pivots (fulcrums) 230A 230B, and multiple pressure-controlled zones 236A-238B to control the applied bending moments and to secure the device 22 to the pivots 230A 230B.

Further, the device holder 220 has relatively high reticle pitching stiffness, and relatively high dynamic modes. Further, the device holder 220 is relatively simple to manufacture and assemble, and is easy to expand the design for higher-order bending.

Moreover, the device holder 220 has a relatively large bending range and a relatively large holding force with only line contact at the pivots 230A 230B. Additionally, the holding and bending mechanisms are integrated together.

Additionally, the device holder 220 is compatible with a conventional sized or larger sized pellicle frame.

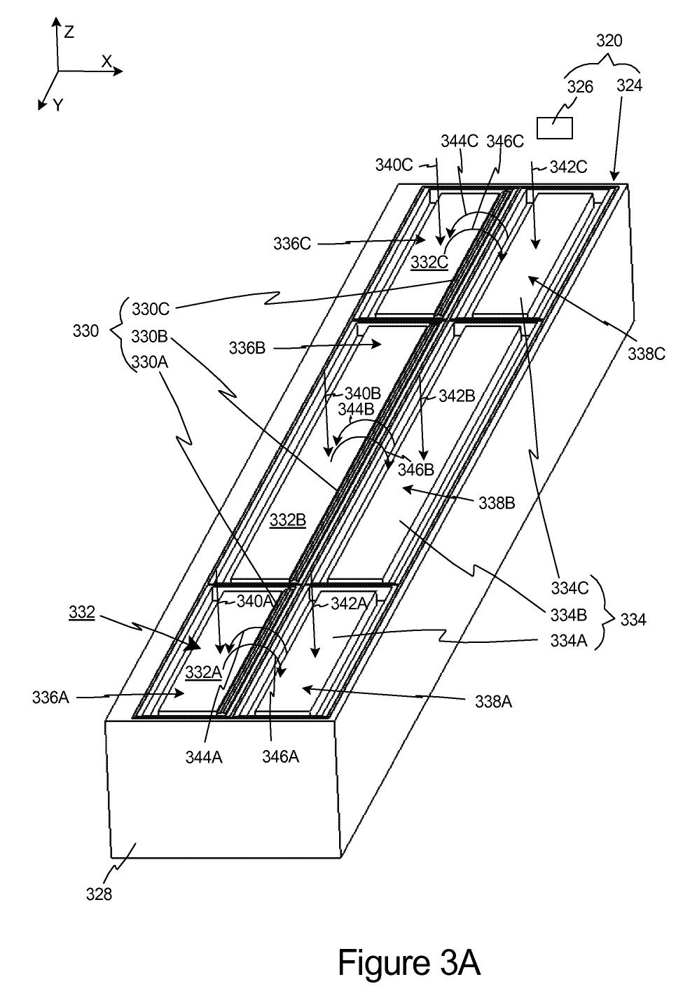

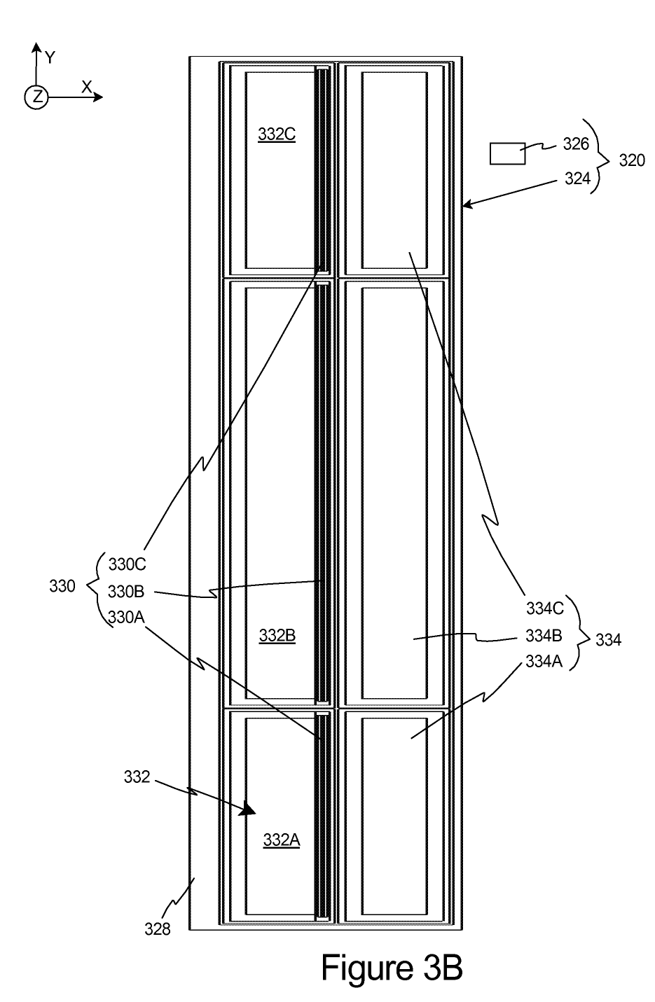

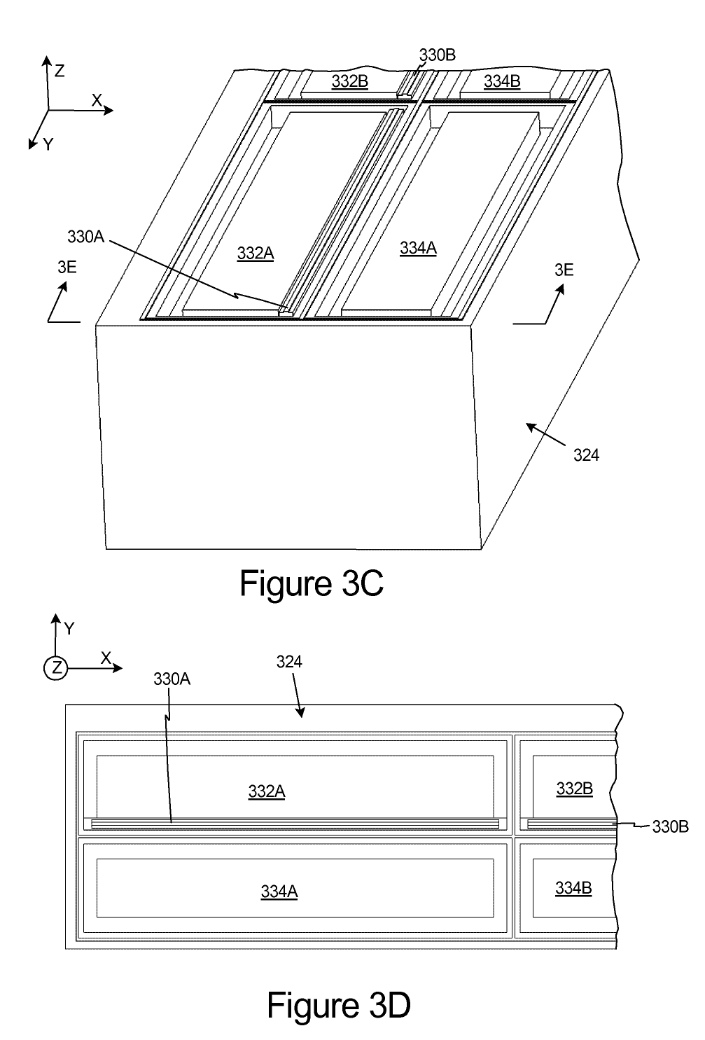

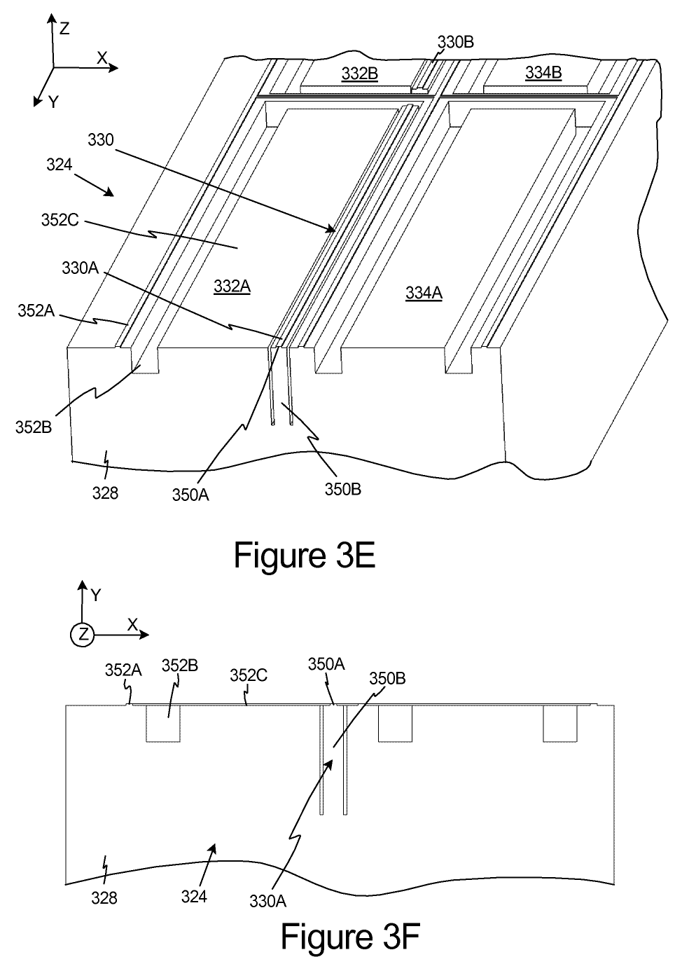

FIG. 3A is a perspective view and FIG. 3B is a top view of one embodiment of the holder 324 of the device holder 320 that can be used as either the first holder or the second holder. In this embodiment, the holder 324 includes the holder housing 328 that defines (i) the pivot 330; (ii) the distal region 332; and (iii) the proximal region 334. Further, the pivot 330 provides an area of approximate line contact along the Y axis with the device 22 (illustrated in FIG. 2). In certain embodiments, the pivot 330 extends almost the entire length of the device 22 along the Y axis.

In one embodiment, (i) the pivot 330 is divided into a plurality of pivot sections, namely a front pivot section 330A, a middle pivot section 330B, and a rear pivot section 330B that are aligned along the Y axis; (ii) the distal region 332 is divided into a plurality of distal sub-regions, namely a front distal sub-region 332A, a middle distal sub-region 332B, and a rear distal sub-region 332C that are aligned along the Y axis; and (iii) the proximal region 334 is divided into a plurality of proximal sub-regions, namely a front proximal sub-region 334A, a middle proximal sub-region 334B, and a rear proximal sub-region 334C that are aligned along the Y axis. Alternatively, (i) the pivot 330 can be divided into more than three or fewer than three pivot sections; (ii) the distal region 332 can be divided into more than three or fewer than three distal sub-regions; and/or (iii) the proximal region 334 can be divided into more than three or fewer than three proximal sub-regions.

In this embodiment, the middle pivot section 330B is larger than the front pivot section 330A and the rear pivot section 330C, and the front pivot section 330A is approximately the same size as the rear pivot section 330B. For example, the middle pivot section 330B can be approximately two times bigger than the front pivot section 330A. Alternatively, each pivot section 330A, 330B, 330C can be approximately the same size or the proportions can be different than that illustrated in FIGS. 3A and 3B.

Similarly, in this embodiment, the middle distal sub-region 332B is larger than the front distal sub-region 332A and the rear distal sub-region 332C, and the front distal sub-region 332A is approximately the same size as the rear distal sub-region 332B. For example, the middle distal sub-region 332B can be approximately two times bigger than the front distal sub-region 332A. Alternatively, each distal sub-region 332A, 332B, 332C can be approximately the same size or the proportions can be different than that illustrated in FIGS. 3A and 3B.

Moreover, in this embodiment, the middle proximal sub-region 334B is larger than the front proximal sub-region 334A and the rear proximal sub-region 334C, and the front proximal sub-region 334A is approximately the same size as the rear proximal sub-region 334B. For example, the middle proximal sub-region 334B can be approximately two times bigger than the front proximal sub-region 334A. Alternatively, each proximal sub-region 334A, 334B, 334C can be approximately the same size or the proportions can be different than that illustrated in FIGS. 3A and 3B.

Further, this embodiment, (i) the front pivot section 330A is positioned in the front distal sub-region 332A; (ii) the middle pivot section 330B is positioned in the middle distal sub-region 332B; and (iii) the rear pivot section 330C is positioned in the rear distal sub-region 332C.

With the design illustrated in FIGS. 3A and 3B, the device 22 (illustrated in FIG. 2) adjacent the holder 324 creates (i) a pressure controlled front distal zone 336A at the front distal sub-region 332A; (ii) a pressure controlled middle distal zone 336B at the middle distal sub-region 332B; (iii) a pressure controlled rear distal zone 336C at the rear distal sub-region 332C; (iv) a pressure controlled front proximal zone 338A at the front proximal sub-region 334A; (v) a pressure controlled middle proximal zone 338B at the middle proximal sub-region 334B; and (vi) a pressure controlled rear proximal zone 338C at the rear proximal sub-region 338C.

In certain embodiments, the pressure source 326 individually controls the pressure at each zone 336A, 336B, 336C, 338A, 338B, 338C. In one non-exclusive embodiment, the pressure source 326 individually controls the pressure in each zone 336A, 336B, 336C, 338A, 338B, 338C to be at a negative pressure.

A provided herein, (i) a negative front distal pressure in the front distal zone 336A will create a front distal force 340A downward on the device 22, and a front distal moment 344A on the device 22 because of the offset positioning of the pivot 330; (ii) a negative middle distal pressure in the middle distal zone 336B will create a middle distal force 340B downward on the device 22, and a middle distal moment 344B on the device 22 because of the offset positioning of the pivot 330; (iii) a negative rear distal pressure in the rear distal zone 336C will create a rear distal force 340C downward on the device 22, and a rear distal moment 344C on the device 22 because of the offset positioning of the pivot 330; (iv) a negative front proximal pressure in the front proximal zone 338A will create a front proximal force 342A downward on the device 22, and a front proximal moment 346A on the device 22 because of the offset positioning of the pivot 330; (v) a negative middle proximal pressure in the middle proximal zone 338B will create a middle proximal force 342B downward on the device 22, and a middle proximal moment 346B on the device 22 because of the offset positioning of the pivot 330; and (vi) a negative rear proximal pressure in the rear proximal zone 338C will create a rear proximal force 340C downward on the device 22, and a rear proximal moment 346C on the device 22 because of the offset positioning of the pivot 330. In this embodiment, as viewed in FIG. 3A, each distal moment 344A-344C is counterclockwise and each proximal moment is clockwise 346A-346C.

The front forces 340A, 342A will pull the device 22 against the front pivot 330A, the middle forces 340B, 342B will pull the device 22 against the middle pivot 330B, and the rear forces 340C, 342C will pull the device 22 against the rear pivot 330C. In one embodiment, the size of each region 332A-334C can be varied and selected to provide the desired range of possible forces 340A-342C at each respective zone 336A-338C. Further, the pressure at each zone 336A-338C can be individually adjusted to individually adjust each force 340A-342C and each bending moment 334A-346C applied to the device. Thus, the pressure at each zone 336A-338C can be individually adjusted to adjust the holding force and to adjust the shape of the device 22.

It should be noted that higher order bending of the device is possible simply by increasing the number of individually controlled zones.

As a non-exclusive example, the pressure source 326 can individually control the pressure in each at each zone 336A-338C to be between approximately zero and negative eighty kilopascals (0 to −80 kPa). Alternatively, other pressures can be utilized. In one non-exclusive embodiment, the pressure source 326 maintains a constant pressure in each of the distal zones 336A, 336B, 336C at approximately negative seventy kilopascals (−70 kPa), and the pressure source 326 individually adjusts the pressure in each proximal zone 338A, 338B, 338C to be in the range of between approximately negative five to negative sixty kilopascals (−5 to −60 kPa) as needed to achieve the desired bending moments and holding force.

FIG. 3C is a perspective view and FIG. 3D is a top view of a portion of the holder 324 of FIGS. 3A and 3B. FIG. 3E is a perspective view cut-away and FIG. 3F is a cut-away view taken on line 3E-3E in FIG. 3C of a portion of the holder 324. More specifically, FIGS. 3C-3F illustrate (i) the front pivot section 330A; (ii) a portion of the middle pivot section 330B; (iii) the front distal sub-region 332A; (iv) a portion of the middle distal sub-region 332B; (v) the front proximal sub-region 334A; and (vi) a portion of the middle proximal sub-region 334B.

Referring to FIGS. 3E and 3F, in one embodiment, the front pivot section 330A includes a pivot body 350A and a pivot contact 350B. The other pivot sections can be similar in design to the front pivot section 330A. In this embodiment, the pivot body 350A is long (along the Y axis), thin (along the X axis) rectangular shaped beam that extends away from the rest of the holder housing 328. Further, in this embodiment, the pivot contact 350B is long (along the Y axis), very thin (along the X axis), rectangular shaped tab that extends upward from the pivot body 350A. In this embodiment, the pivot contact 350B is the highest point of the holder 324 and the only area of the holder 324 that contacts the device 22.

As a non-exclusive embodiment, the pivot contact 350B can have a thickness (along the X axis) that is between approximately 50 microns and 500 microns. This leads to a normal line contact between the pivot contact 350B and the device 22 instead of a planar contact.

In one non-exclusive embodiment, the entire holder housing 328 is made as a monolithic structure. Alternatively, each pivot section 330A can be a separate structure that is attached to the rest of the holder housing 328. Still alternatively, each pivot contact 350B can be made of a different material than the pivot body 350A. These designs may allow for the fine tuning of the flexing characteristics of each pivot section 330A.

The size, shape and design of each sub-region 332A, 332B, 334A, 334B can vary. In the non-exclusive embodiment illustrated in FIGS. 3E and 3F, each sub-region 332A, 332B, 334A, 334B is generally rectangular shaped and includes a region lip 352A, a region channel 352B and a region damping area 352C.

The region seal 352A defines the boundary of each sub-region 332A, 332B, 334A, 334B. In one embodiment, the region seal 352A is a generally rectangular lip that extends around the perimeter of the respective sub-region 332A, 332B, 334A, 334B. Further, the device 22 is maintained a relatively small gap away from the region seal 352A with the pivot 330. However, the region seal 352A is close enough to the device 22 to limit the flow of fluid to allow for the control of the pressure in the respective sub-region. As a non-exclusive embodiment, the region seal 352A is maintained a gap that is between approximately 0.5 and 5 microns away from the device 22.

The region channel 352B provides an area to control the pressure in the respective sub-region. In one embodiment, the region channel 352B is a generally rectangular shaped channel in the holder 324.

The region damping area 352C is a raised area that is also relatively close to and spaced apart from the device 22 when the device 22 is positioned on the holder 324. In one non-exclusive embodiment, the region damping area 352C can be spaced apart a gap that is between approximately 0.5 and 20 micrometers from the device 22. However, other distances can be utilized. With this design, the region damping area 352C can provide passive, squeeze film type damping of the device 22 to reduce vibration in the device 22. In one embodiment, the region damping region 352C is a generally rectangular shaped.

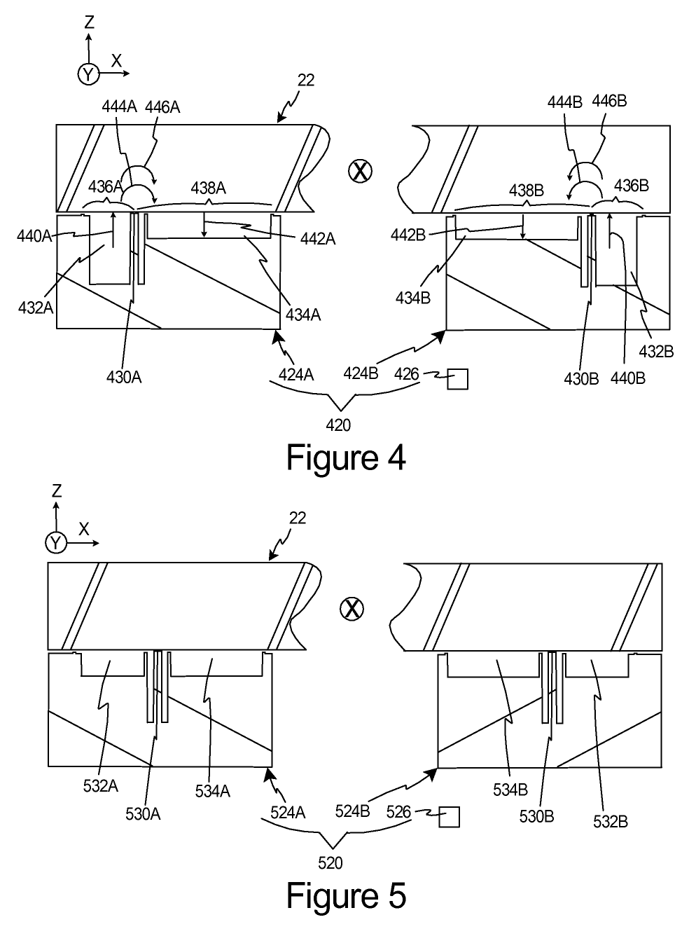

FIG. 4 is a simplified cut-away view of a portion of the device 22 and another embodiment of the device holder 420 including the first holder 424A, the second holder 424B, and the pressure source 426. In this embodiment, (i) the first holder 424A includes the first pivot 430A, the first distal region 432A, and the first proximal region 434A; and (ii) the second holder 424B includes the second pivot 430B, the second distal region 432B, and the second proximal region 434B that are somewhat similar to the corresponding components described above and illustrated in FIG. 2.

However, in this embodiment, (i) the first distal region 432A is smaller than the first proximal region 434A; and (ii) the second distal region 432B is smaller than the second proximal region 434B.

In FIG. 4, (i) the first distal region 432A can include one or more pressure controlled first distal zones 436A (only one is illustrated); (ii) the first proximal region 434A can include one or more pressure controlled first proximal zones 438A (only one is illustrated); (iii) the second distal region 432B can include one or more pressure controlled second distal zones 436B (only one is illustrated); and (iv) the second proximal region 434B can include one or more pressure controlled second proximal zones 438B (only one is illustrated).

Further, in one embodiment, the pressure source 426 individually controls (i) a distal pressure in each distal zone 436A, 436B to be a positive pressure (greater than the environmental pressure), and (ii) a proximal pressure in each proximal zone 438A, 438B to be a negative pressure (below the environmental pressure).

In one embodiment, (i) the positive pressure in the first distal zone 436A will create a first distal force 440A (illustrated as an arrow) upward, and a clockwise, first distal moment 444A on the device 22; (ii) the negative pressure in the first proximal zone 438A will create a first proximal force 442A (illustrated as an arrow) downward, and a clockwise first proximal moment 446A on the device 22; (iii) the positive pressure in the second distal zone 436B will create a second distal force 440B (illustrated as an arrow) upward, and a counterclockwise, second distal moment 444B on the device 22; and (iv) the negative pressure in the second proximal zone 438B will create a second proximal force 442B (illustrated as an arrow) downward, and a counterclockwise second proximal moment 446B on the device 22.

Thus, in this embodiment, (i) the first distal moment 444A is in the same direction as the first proximal moment 446A, and (ii) the second distal moment 444B is in the same direction as the second proximal moment 446B.

Further, the size of each region 432A, 434A, 432B, 434B can be varied and selected to provide the desired range of possible forces 440A, 440B, 442A, 442B and moments 444A, 444B, 446A, 446C. Further, the pressure at each zone 436A, 436B, 438A, 438B can be individually adjusted to individually adjust each force 440A, 440B, 442A, 442B and each moments 444A, 444B, 446A, 446C to achieve the desired holding force and bending moments imparted on the device 22.

FIG. 5 is a simplified cut-away view of a portion of the device 22 and yet another embodiment of the device holder 520 including the first holder 524A, the second holder 524B, and the pressure source 526. In this embodiment, (i) the first holder 524A includes the first pivot 530A, the first distal region 532A, and the first proximal region 534A; and (ii) the second holder 524B includes the second pivot 530B, the second distal region 532B, and the second proximal region 534B that are somewhat similar to the corresponding components described above and illustrated in FIG. 2.

However, in this embodiment, (i) first pivot 530A is positioned in between the first distal region 532A and the first proximal region 534A; and (ii) the second pivot 530B is positioned between the second distal region 532B and the second proximal region 534B.

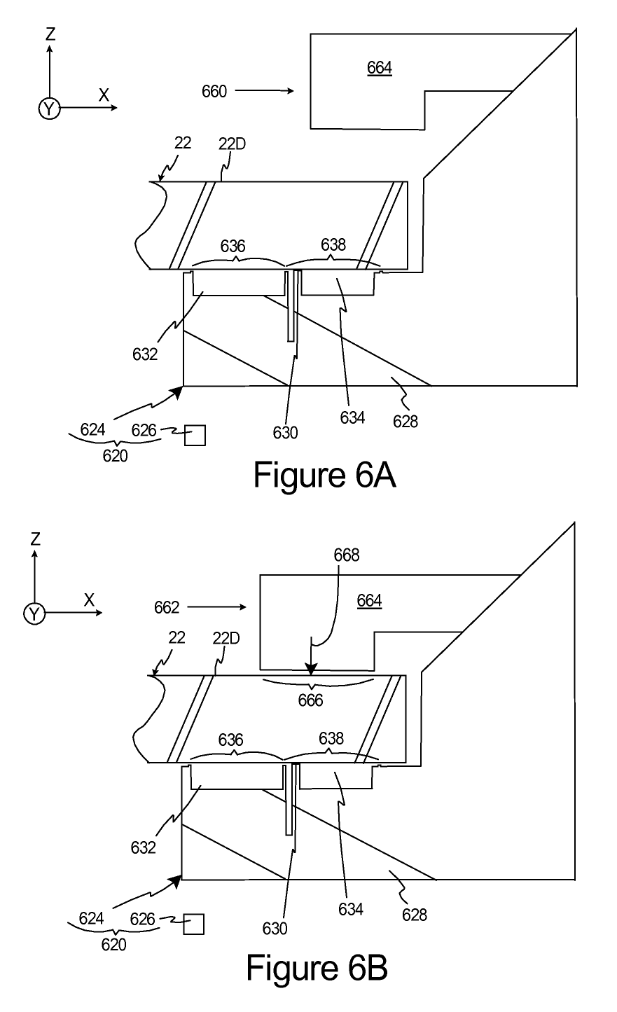

FIG. 6A is a simplified cut-away view of a portion of the device 22, and a portion of another embodiment of a device holder 620 in an unlocked position 660 and FIG. 6B illustrates the portion of the device holder 620 in a locked position 662. In this embodiment, the device holder 620 includes a pair of spaced apart holders 624 (only one is illustrated but both can be similar), and the pressure source 626. In this embodiment, each holder 624 includes the pivot 630, the distal region 632, and the proximal region 634 that are similar to the corresponding components described above. Further, the pressure source 626 controls (i) a distal pressure in the distal region 632 to create one or more pressure controlled, distal zones 636 (only one is visible); and (ii) a proximal pressure in the proximal region 634 to create one or more pressure controlled proximal zones 638 (only one is visible).

However, in this embodiment, the holder 624 additionally includes an upper chuck 664 that is movable relative to the rest of the holder housing 628 between the unlocked position 660 and the locked position 662, and selectively locked in each position 660, 662. When the upper chuck 664 is in the locked position 662, the pressure source 626 can control the pressure between the upper chuck 664 and the top 22D of the device 22 to create one or more pressure controlled upper zones 666 (only one is illustrated in FIG. 6B). In one embodiment, the pressure source 626 can control the pressure in the upper zone 666 to be a positive pressure. This will create an upper force 668 (illustrated as an arrow) downward on the device 22 that increases the holding force of the device holder 620 and increases the moments.

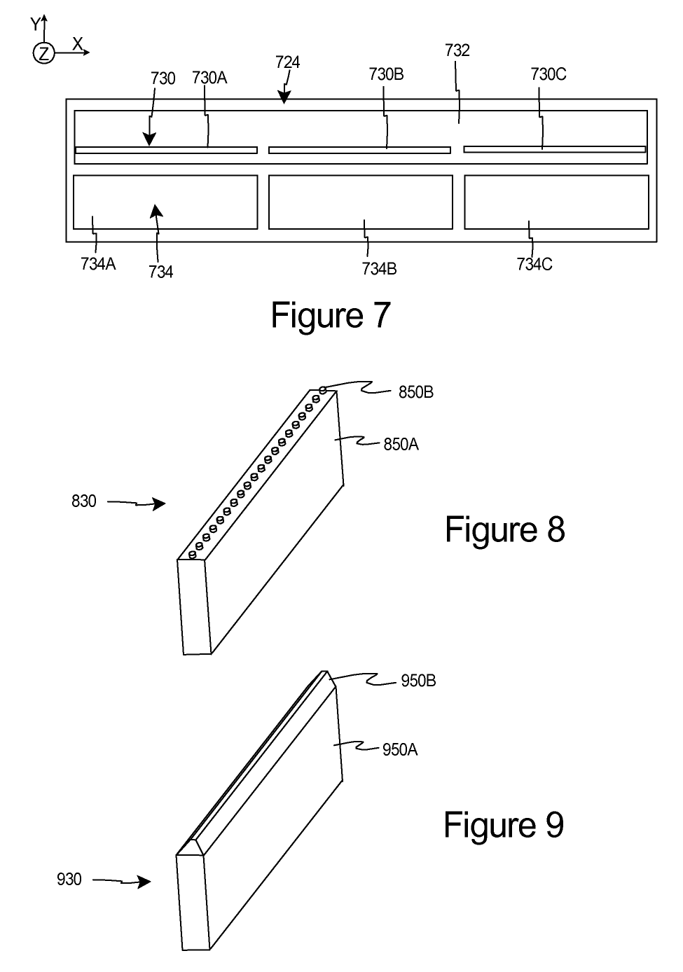

FIG. 7 is a top view of another embodiment of a holder 724 that includes a pivot 730, a distal region 732, and a proximal region 734 that are similar to the corresponding components described above and illustrated in FIGS. 3A-3F. However, in this embodiment, the distal region 732 is not divided into sub-regions. Thus, there is only one pressure controlled distal zone.

Further, in the embodiment, the pivot 730 is divided into three, substantially equally sized pivot sections 730A, 730B, 730C, and the proximal region 734 is divided into three, substantially equally sized proximal sub-regions 734A, 734B, 734C. Thus, there will be three separate pressure controlled proximal zones.

FIG. 8 is a simplified perspective view of another embodiment of a pivot 830 having features of the present invention. In this embodiment, the pivot 830 includes a pivot body 850A that is somewhat similar to the corresponding component described above, and a pivot contact 850B that is slightly different. More specifically, in this embodiment, the pivot contact 850B includes a plurality of spaced apart cylindrical protrusions (e.g. one-dimensional array of pins) that contact the device 22 (illustrated in FIG. 1).

FIG. 9 is a simplified perspective view of yet another embodiment of a pivot 930 having features of the present invention. In this embodiment, the pivot 930 includes a pivot body 950A that is somewhat similar to the corresponding component described above, and a pivot contact 950B that is slightly different. More specifically, in this embodiment, the pivot contact 950B defines a blunted knife edge that contacts the device 22 (illustrated in FIG. 1) and has a substantially trapezoidal shaped cross-section.

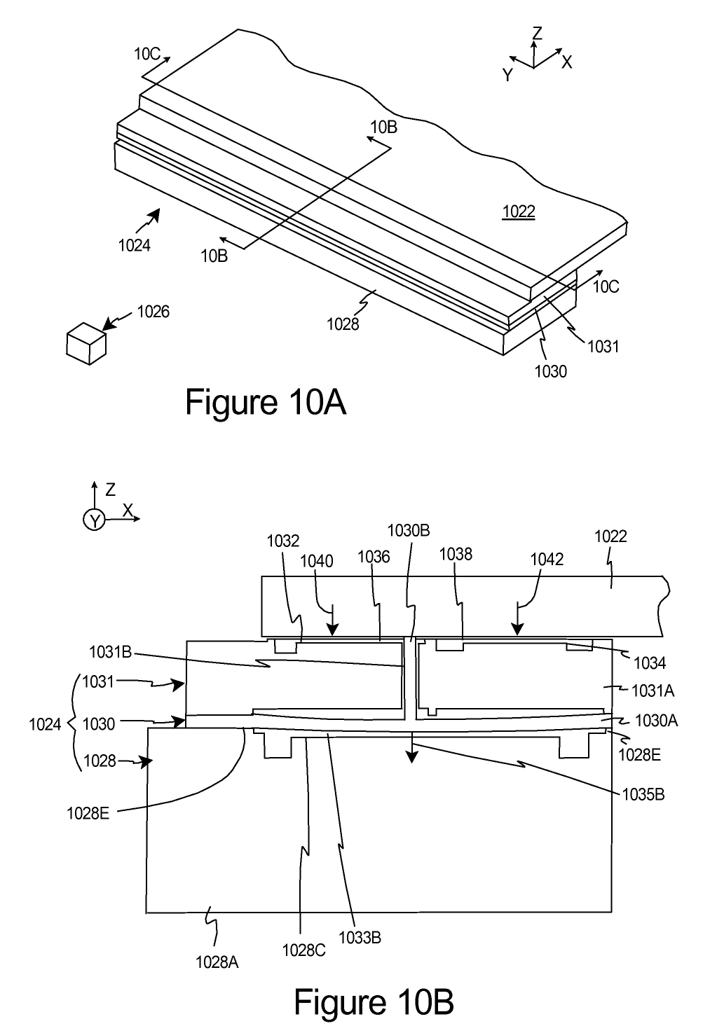

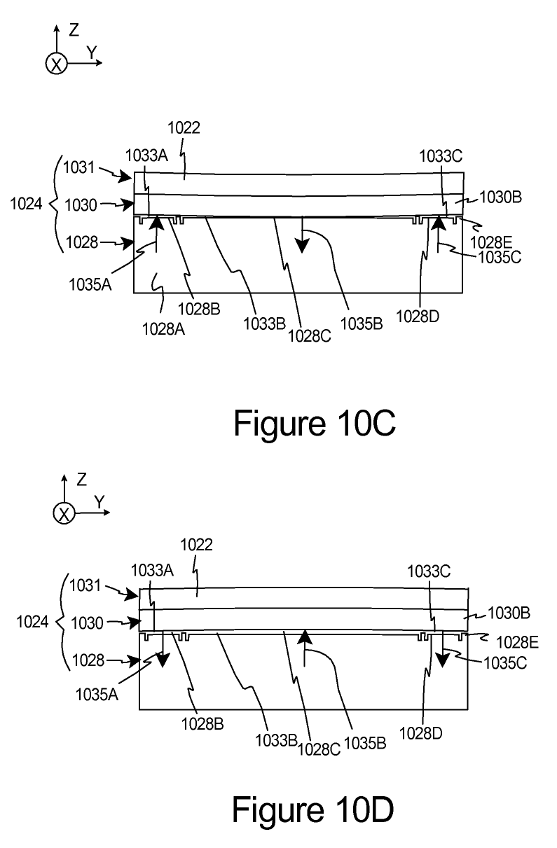

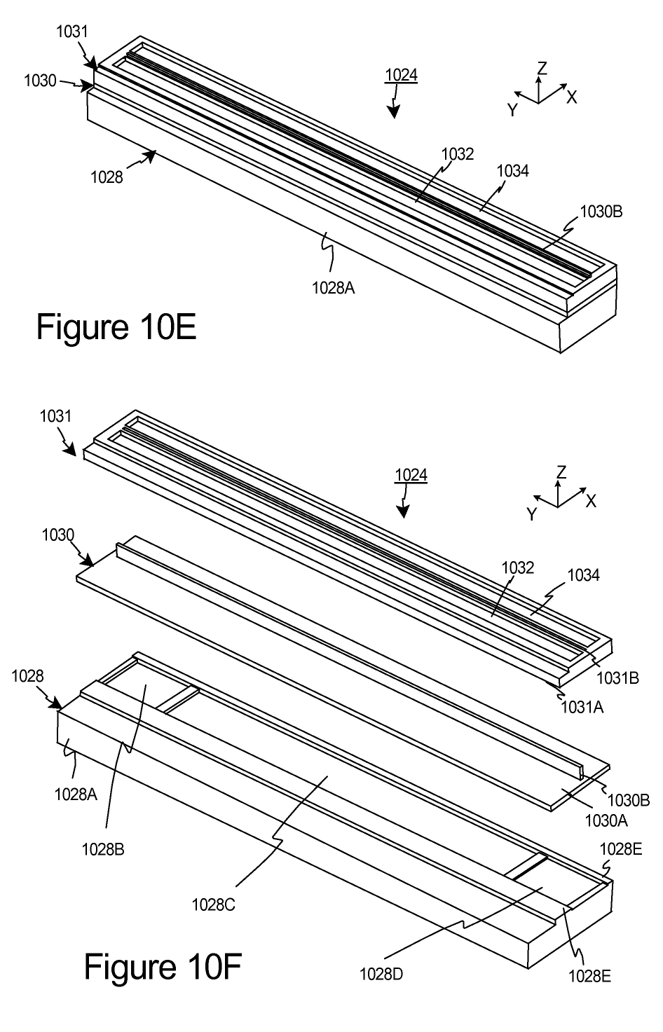

FIG. 10A is a simplified partially cut away view of a device 1022, a pressure source 1026, and another embodiment of a holder 1024 that can be used as either the first holder or the second holder. In this embodiment, the holder 1024 includes a lower, first holder housing 1028, a flexible pivot assembly 1030, and an upper, second holder housing 1031. The design of each of these components can be varied pursuant to the teachings provided herein.

FIGS. 10B and 10C are alternative, simplified cut away views from FIG. 10A that illustrate the device 1022, and the lower, holder housing 1028, the flexible pivot assembly 1030, and the upper, second holder housing 1031 of the holder 1024. In this embodiment, the first holder housing 1028 includes a housing body 1028A that defines one or more adjustment regions 1028B, 1028C, 1028D, and a pair of spaced apart support areas 1028E which are positioned below the pivot assembly 1030. The number, and design, size and shape of adjustment regions 1028B, 1028C, 1028D can be varied to achieve the desired control over the shape of the pivot assembly 1030 and the device 1022. In one embodiment, the first holder housing 1028 includes three spaced apart and separate adjustment regions, namely a front, first adjustment region 1028B, a middle, second adjustment region 1028C, and a rear, third adjustment region 1028D. In this embodiment, the front, first adjustment region 1028B and the rear, third adjustment region 1028D are substantially equally sized, and the middle, second adjustment region 1028C is larger than the other two adjustment regions 1028B, 1028D. Alternatively, for example, the design can include more than three or fewer than three adjustment regions 1028B, 1028C, 1028D.

In one embodiment, each adjustment region 1028B, 1028C, 1028D is a depression in the housing body 1028A; and the support areas 1028E are a raised area that surrounds the adjustment regions 1028C, 1028D, 1028E. Further, the support areas 1028E can support a perimeter of the pivot assembly 1030, while allowing a portion of the pivot assembly 1030 to move and flex relative to the holder housings 1028, 1031.

With the present design, the pressure source 1026 (illustrated in FIG. 10A) can independently control the pressure at each of these adjustment regions 1028B, 1028C, 1028D to control the shape of the pivot assembly 1030. More specifically, in one embodiment, the pressure source 1026 controls (i) a first pressure between the pivot assembly 1030 and the first adjustment region 1028B to create a pressure controlled, first adjustment zone 1033A, (ii) a second pressure between the pivot assembly 1030 and the second adjustment region 1028C to create a pressure controlled, second adjustment zone 1033B, and (i) a third pressure between the pivot assembly 1030 and the third adjustment region 1028C to create a pressure controlled, third adjustment zone 1033C.

As provided herein, the pressure source 1026 can individually control the pressure in each of the zones 1033A, 1033B, 1033C to be below the environmental pressure (“negative pressure”) or above the environmental pressure (“positive pressure”) as required to achieve the desired shaped of the pivot assembly 1030 and the desired shape of the device 1022.

As illustrated in the non-exclusive embodiment of FIG. 10C, (i) a positive pressure in the first adjustment zone 1033A will create a first adjustment force 1035A upward on the pivot assembly 1030, (ii) a negative pressure in the second adjustment zone 1033B will create a second adjustment force 1035B downward on the pivot assembly 1030, and (i) a positive pressure in the third adjustment zone 1033C will create a third adjustment force 1035C upward on the pivot assembly 1030. With this design, the pressure source 1026 can be used to accurately bend the pivot assembly 1030 and the device 1022 in a concave fashion about the X axis.

Alternatively, as illustrated in FIG. 10D, (i) a negative pressure in the first adjustment zone 1033A will create a first adjustment force 1035A downward on the pivot assembly 1030, (ii) a positive pressure in the second adjustment zone 1033B will create a second adjustment force 1035B upward on the pivot assembly 1030, and (i) a negative pressure in the third adjustment zone 1033C will create a third adjustment force 1035C downward on the pivot assembly 1030. With this design, the pressure source 1025 can be used to accurately bend the pivot assembly 1030 and the device 1022 in a convex fashion about the X axis.

It should be noted that the pressures in each of the adjustment zones 1033A, 1033B, 1033C can be individually adjusted to achieve the desired shape of the pivot assembly 1030 and the device 1022.

It should also be noted that although each adjustment force 1035A, 1035B, 1035C is illustrated as a single arrow centered in its respective zone 1033A, 1033B, 1033C, in reality, each force 1035A, 1035B, 1035C is actually distributed along the area of its respective zone 1033A, 1033B, 1033C. Should also note that negative pressure can be used in zones 1033A, 1033B, 1033C to achieve desired shape of the pivot assembly 1030.

Referring back to FIGS. 10B and 10C, the pivot assembly 1030 is flexible and includes a flexible, generally flat (when not flexed) pivot base 1030A, and a flexible pivot 1030B that extends upward away from the pivot base 1030A. In this embodiment, the pivot 1030B again provides an area of approximate line contact along the Y axis with the device 1022. In certain embodiments, the pivot 1030B is a generally rectangular shaped beam that extends almost the entire length of the device 1022 along the Y axis. Alternatively, the pivot 1030B can extend only a portion of the length of the device 1022 or the pivot 1030B can be divided into multiple pivot sections. With this design, flexure of the pivot base 1030A upward moves that portion of the pivot 1030B upward and flexure of the pivot base 1030A downward moves that portion of the pivot 1030B downward.

With this design, the pivot 1030B (e.g. a blade) can conform easily to device 1022 to reduce unwanted distortion from flatness errors of the holder 1024 or device 1022 or particles between the pivot 1030B and the device 1022. In other words, the holder 1024 holds the device 1022 in a more kinematic manner. As nonexclusive examples, the pivot assembly 1030 can be made of ceramics or glass that allow for a few microns of flexing.

The second holder housing 1031 includes a housing body 1031A that defines a distal region 1032; a proximal region 1034, and a pass-thru 1031B that receives the pivot 1030B and allows the pivot to extend through the second holder housing 1031. In this embodiment, the second holder housing 1031 rests on the pivot base 1030A above the support rim 1028E and the second holder housing 1031 is shaped to allow for motion of a portion of the pivot base 1030A and the pivot 1030B relative to the second holder housing 1031.

In one embodiment, the pressure source 1026 controls (i) a distal pressure in the distal region 1032 to create a pressure controlled, first distal zone 1036 between the device 1022 and the second holder housing 1031; and (ii) a proximal pressure in the proximal region 1034 to create a pressure controlled proximal zone 1038 between the device 1022 and the second holder housing 1031. As provided herein, the pressure source 1026 can individually control the pressure in each of the zones 1036, 1038 to be below the environmental pressure or above the environmental pressure as required to achieve the desired shaped of the device 1022.

With this embodiment, (i) a negative pressure in the distal zone 1036 will create a distal force 1040 (illustrated as an arrow) downward on the device 1022; and (ii) a negative force in the proximal zone 1038 will create a proximal force 1042 (illustrated as an arrow) downward on the device 1022. With this design, the forces 1040, 1042 will pull/urge the device 1022 against the pivot 1030B.

In the embodiment illustrated in FIG. 10B, the proximal force 1042 and the bulk of the distal force 1040 are positioned on opposite sides of the pivot 1030A. With this design the pressure in the zone 1036, 1038 can be individually adjusted to individually adjust each force 1040, 1042 to adjust the holding force of the device holder 1020.

Moreover, the pressure in each zone 1036, 1038 can be individually adjusted to individually adjust each force 1040, 1042, and individually adjust each moment that is applied to the device 1022 to control the bending of the device about the Y axis, and ultimately control the shape of the device 1022.

With the present design, the device holder 1020 can have a relatively large bending range (e.g. +/−1 um as a non-exclusive example) and a relatively large holding force with only line contact at the pivot 1030B. Further, in certain embodiments, control of the bending about the X axis is independent of the control of the bending about the Y axis. Stated in another fashion, the first bending stroke is achieved by vacuum pressures acting on the device 1022, and the second bending stroke is achieved by vacuum pressures acting on the device 1022 through the pivot 1030B. In the embodiment illustrated in FIGS. 10A-10D, the holder 1024 can have a relatively large second bending stroke.

FIG. 10E is a more detailed, perspective view, and FIG. 10F is an exploded perspective view of the holder 1024 of FIG. 10A including the first holder housing 1028, the pivot assembly 1030, and the second holder housing 1031. It should be noted that (i) the housing body 1028A, (ii) the 1028B adjustment regions 1028B, 1028C, 1028D, (iii) the support rim 1028E, (iv) the pivot base 1030A, (v) the pivot 1030B, (vi) the housing body 1031A, (vii) the pass-thru 1031B, (viii) the distal region 1032, (ix) the proximal region 1034 are referenced in FIG. 10E and/or FIG. 10F.

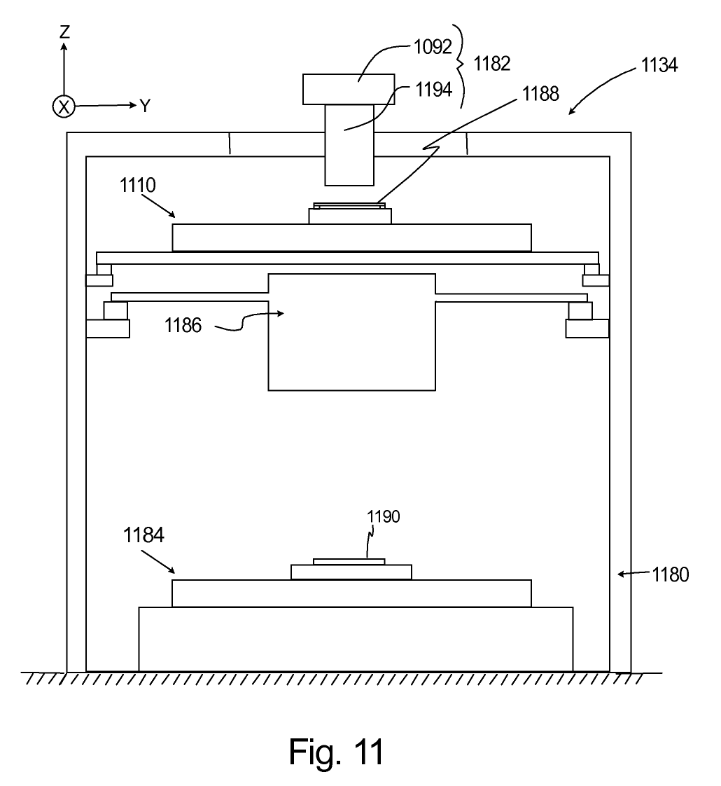

FIG. 11 is a schematic view illustrating an exposure apparatus 1130 useful with the present invention. The exposure apparatus 1130 includes the apparatus frame 1180, an illumination system 1182 (irradiation apparatus), a reticle stage assembly 1110, an optical assembly 1186 (lens assembly), and a wafer stage assembly 1184. The device holders provided herein can be used in the reticle stage assembly 1110 and/or the wafer stage assembly 1184.

The exposure apparatus 1130 is particularly useful as a lithographic device that transfers a pattern (not shown) of an integrated circuit from the reticle 1188 onto the semiconductor wafer 1190. The exposure apparatus 1130 mounts to the mounting base 1124, e.g., the ground, a base, or floor or some other supporting structure.

The apparatus frame 1180 is rigid and supports the components of the exposure apparatus 1130. The design of the apparatus frame 1180 can be varied to suit the design requirements for the rest of the exposure apparatus 1130.

The illumination system 1182 includes an illumination source 1192 and an illumination optical assembly 1194. The illumination source 1192 emits a beam (irradiation) of light energy. The illumination optical assembly 1194 guides the beam of light energy from the illumination source 1192 to the optical assembly 1186. The beam illuminates selectively different portions of the reticle 1088 and exposes the semiconductor wafer 1190. In FIG. 11, the illumination source 1192 is illustrated as being supported above the reticle stage assembly 1184. Alternatively, the illumination source 1192 can be secured to one of the sides of the apparatus frame 1180 and the energy beam from the illumination source 1192 is directed to above the reticle stage assembly 1184 with the illumination optical assembly 1194.

The optical assembly 1186 projects and/or focuses the light passing through the reticle to the wafer. Depending upon the design of the exposure apparatus 1130, the optical assembly 1186 can magnify or reduce the image illuminated on the reticle.

There are a number of different types of lithographic devices. For example, the exposure apparatus 1130 can be used as scanning type photolithography system that exposes the pattern from the reticle 1188 onto the wafer 1190 with the reticle 1188 and the wafer 1190 moving synchronously. Alternatively, the exposure apparatus 1130 can be a step-and-repeat type photolithography system that exposes the reticle 1188 while the reticle 1188 and the wafer 1190 are stationary.

However, the use of the exposure apparatus 1130 and the stage assemblies provided herein are not limited to a photolithography system for semiconductor manufacturing. The exposure apparatus 1130, for example, can be used as an LCD photolithography system that exposes a liquid crystal display device pattern onto a rectangular glass plate or a photolithography system for manufacturing a thin film magnetic head. Further, the present invention can also be applied to a proximity photolithography system that exposes a mask pattern by closely locating a mask and a substrate without the use of a lens assembly. Additionally, the present invention provided herein can be used in other devices, including other semiconductor processing equipment, elevators, machine tools, metal cutting machines, inspection machines and disk drives.

As described above, a photolithography system according to the above described embodiments can be built by assembling various subsystems, including each element listed in the appended claims, in such a manner that prescribed mechanical accuracy, electrical accuracy, and optical accuracy are maintained. In order to maintain the various accuracies, prior to and following assembly, every optical system is adjusted to achieve its optical accuracy. Similarly, every mechanical system and every electrical system are adjusted to achieve their respective mechanical and electrical accuracies. The process of assembling each subsystem into a photolithography system includes mechanical interfaces, electrical circuit wiring connections and air pressure plumbing connections between each subsystem. Needless to say, there is also a process where each subsystem is assembled prior to assembling a photolithography system from the various subsystems. Once a photolithography system is assembled using the various subsystems, a total adjustment is performed to make sure that accuracy is maintained in the complete photolithography system. Additionally, it is desirable to manufacture an exposure system in a clean room where the temperature and cleanliness are controlled.

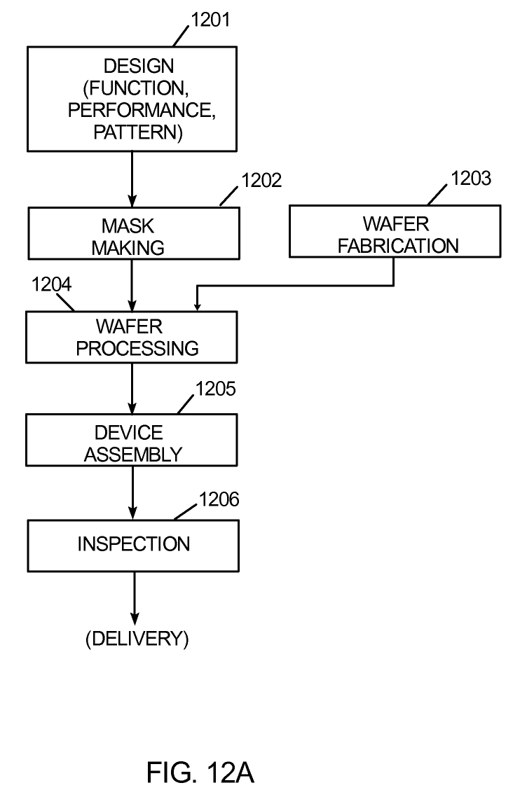

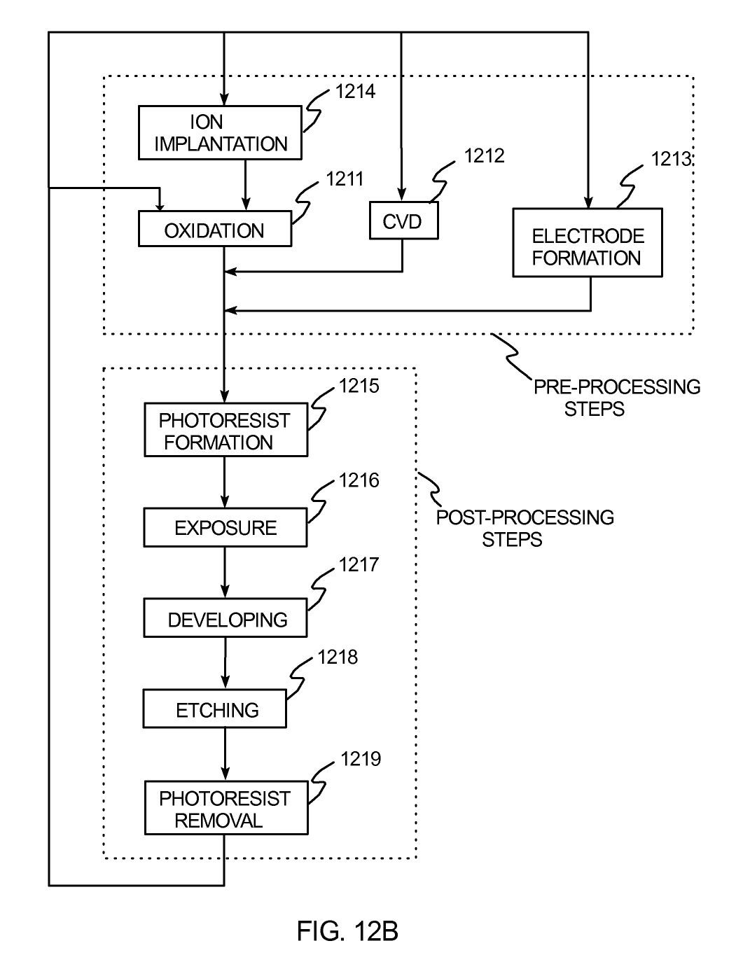

Further, semiconductor devices can be fabricated using the above described systems, by the process shown generally in FIG. 12A. In step 1201 the device's function and performance characteristics are designed. Next, in step 1202, a mask (reticle) having a pattern is designed according to the previous designing step, and in a parallel step 1203 a wafer is made from a silicon material. The mask pattern designed in step 1202 is exposed onto the wafer from step 1203 in step 1204 by a photolithography system described hereinabove in accordance with the present invention. In step 1205 the semiconductor device is assembled (including the dicing process, bonding process and packaging process), finally, the device is then inspected in step 1206.

FIG. 12B illustrates a detailed flowchart example of the above-mentioned step 1204 in the case of fabricating semiconductor devices. In FIG. 12B, in step 1211 (oxidation step), the wafer surface is oxidized. In step 1212 (CVD step), an insulation film is formed on the wafer surface. In step 1213 (electrode formation step), electrodes are formed on the wafer by vapor deposition. In step 1214 (ion implantation step), ions are implanted in the wafer. The above mentioned steps 1211-1214 form the preprocessing steps for wafers during wafer processing, and selection is made at each step according to processing requirements.

At each stage of wafer processing, when the above-mentioned preprocessing steps have been completed, the following post-processing steps are implemented. During post-processing, first, in step 1215 (photoresist formation step), photoresist is applied to a wafer. Next, in step 1216 (exposure step), the above-mentioned exposure device is used to transfer the circuit pattern of a mask (reticle) to a wafer. Then in step 1217 (developing step), the exposed wafer is developed, and in step 1218 (etching step), parts other than residual photoresist (exposed material surface) are removed by etching. In step 1219 (photoresist removal step), unnecessary photoresist remaining after etching is removed.

Multiple circuit patterns are formed by repetition of these preprocessing and post-processing steps.

While the particular stage assembly as shown and disclosed herein is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. A stage assembly that moves a device having a predetermined axis, the stage assembly being positioned in an environment that is at an environmental pressure, the stage assembly comprising:
a stage including a stage housing, and a device holder that selectively secures the device to the stage housing, the device holder including a first holder that defines a first pivot that engages the device, the first holder creating (i) a pressure controlled, first distal zone between the first holder and device that is at a first distal pressure, and (ii) a pressure controlled, first proximal zone between the first holder and device that is at a first proximal pressure; the first proximal zone being closer to the predetermined axis than the first distal zone; wherein at least one of the first pressures is less than the environmental pressure; wherein the first distal pressure in the first distal zone generates a first distal moment on the device near the first pivot; and wherein the first proximal pressure in the first proximal zone generates a first proximal moment on the device near the first pivot.

2. The stage assembly of claim 1 further comprising a stage mover assembly that moves the stage.

3. The stage assembly of claim 1 wherein each of the first pressures are less than the environmental pressure; and wherein the first distal moment is substantially opposite in direction to the first proximal moment.

4. The stage assembly of claim 1 wherein one of the first pressures is greater than the environmental pressure; and wherein the first distal moment is substantially the same direction as the first proximal moment.

5. The stage assembly of claim 1 wherein the first pressures are controlled to control the shaped of the device.

6. The stage assembly of claim 1 wherein the first pivot is positioned in the first distal zone.

7. The stage assembly of claim 1 wherein the first pivot is positioned intermediate the first distal zone and the first proximal zone.

8. The stage assembly of claim 1 wherein the first pivot provides an area of approximate line contact with the device.

9. The stage assembly of claim 1 wherein the device holder includes a second holder that defines a second pivot that engages the device and that is spaced apart from the first pivot; wherein the second holder creates (i) a pressure controlled, second distal zone between the second holder and device that is at a second distal pressure, and (ii) a pressure controlled, second proximal zone between the second holder and device that is at a second proximal pressure; the second proximal zone being closer to the central axis than the second distal zone; wherein at least one of the second pressures is less than the environmental pressure; wherein the second distal pressure in the second distal zone generates a second distal moment on the device near the second pivot; and wherein the second proximal pressure in the second proximal zone generates a second proximal moment on the device near the second pivot.

10. The stage assembly of claim 1 wherein the device is retained a relatively small fluid gap away from the first holder so that the device experiences squeeze film damping.

11. The stage assembly of claim 1 wherein the device holder further includes a pressure source that is in fluid communication with the first holder to create a pressure controlled, adjustment zone between the first holder and the first pivot that bends the first pivot.

12. An exposure apparatus including the stage assembly of claim 1 retaining the device, and an illumination system that directs an energy beam at the device.

13. A stage assembly that moves a device including a predetermined axis, the stage assembly being positioned in an environment that is at an environmental pressure, the stage assembly comprising:
a stage including a stage housing, and a device holder that selectively secures the device to the stage housing, the device holder including:
a first holder that defines a first pivot that engages the device, the first pivot defining an area of approximate line contract with the device; and
a second holder that defines a second pivot that engages the device, the second pivot being spaced apart from the first pivot, the second pivot defining an area of approximate line contract with the device;
wherein the first holder creates (i) a pressure controlled, first distal zone between the first holder and the device that is at a first distal pressure, (ii) a pressure controlled, first proximal zone between the first holder and the device that is at a first proximal pressure, the first proximal zone being closer to the predetermined axis than the first distal zone; wherein the second holder creates (iii) a pressure controlled, second distal zone between the second holder and the device that is at a second distal pressure, and (iv) a pressure controlled, second proximal zone between the second holder and the device that is at a second proximal pressure, the second proximal zone being closer to the predetermined axis than the second distal zone; wherein each of the pressures is less than the environmental pressure; wherein the first distal pressure in the first distal zone generates a first distal moment on the device near the first pivot; wherein the first proximal pressure in the first proximal zone generates a first proximal moment on the device near the first pivot; wherein the second distal pressure in the second distal zone generates a second distal moment on the device near the second pivot; wherein the second proximal pressure in the second proximal zone generates a second proximal moment on the device near the second pivot; and wherein the pressures are controlled to control the shape of the device.

14. The stage assembly of claim 13 further comprising a stage mover assembly that moves the stage.

15. The stage assembly of claim 13 wherein the first distal moment is substantially opposite in direction to the first proximal moment, and wherein the second distal moment is substantially opposite in direction to the second proximal moment.

16. The stage assembly of claim 13 wherein the first pivot is positioned in the first distal zone, and wherein the second pivot is positioned in the second distal zone.

17. The stage assembly of claim 13 wherein the device holder further includes a pressure source that is in fluid communication with the first holder to create a pressure controlled, adjustment zone between the first holder and the first pivot that bends the first pivot.

18. A stage assembly that moves a device having a predetermined axis, the stage assembly being positioned in an environment that is at an environmental pressure, the stage assembly comprising:
a stage including a stage housing, and a device holder that selectively secures the device to the stage housing, the device holder including a first holder that defines a first pivot that engages the device, wherein the device holder creates (i) a pressure controlled, first distal zone between the first holder and device that is at a first distal pressure, and (ii) a pressure controlled, first proximal zone between the first holder and device that is at a first proximal pressure; the first proximal zone being closer to the central axis than the first distal zone; and (iii) a pressure controlled, first adjustment zone between the first holder and the first pivot that is a first adjustment zone pressure that is controlled to selectively bend the first pivot.

19. The stage assembly of claim 18 wherein the stage further includes a pressure source that is in fluid communication with the first holder to create (i) a second adjustment zone between the first holder and the first pivot that is at a second adjustment zone pressure, and (ii) a third adjustment zone between the first holder and the first pivot that is at a third adjustment zone pressure; and wherein the pressure source controls the adjustment zone pressures to adjust the shape of the pivot and the shape of the device.

20. The stage assembly of claim 19 wherein one of the adjustment zone pressures is greater than the environmental pressure; and wherein one of the adjustment zone pressures is less than the environmental pressure.

21. The stage assembly of claim 19 wherein the device holder includes a second holder that defines a second pivot that engages the device and that is spaced apart from the first pivot; wherein the second holder creates (i) a pressure controlled, second distal zone between the second holder and device, and (ii) a pressure controlled, second proximal zone between the second holder and device; the second proximal zone being closer to the central axis than the second distal zone; and (iii) a pressure controlled, second adjustment zone between the second holder and the second pivot that is a second adjustment zone pressure that is controlled to selectively bend the second pivot and the device.

22. A method for retaining a device having a central axis, the device being positioned in an environment that is at an environmental pressure, the method comprising the steps of:
positioning the device on a first pivot of a first holder;
generating a first distal moment on the device near the first pivot by creating a pressure controlled, first distal zone between the first holder and the device that is at a first distal pressure; and
generating a first proximal moment on the device near the first pivot by creating a pressure controlled, first proximal zone between the first holder and the device that is at a first proximal pressure; the first proximal zone being closer to the central axis than the first distal zone; wherein at least one of the first pressures is less than the environmental pressure.

23. The method of claim 22 further comprising the step of moving the first holder and the device with a stage mover assembly.

24. The method of claim 22 wherein each of the first pressures is less than the environmental pressure; and wherein the first distal moment is substantially opposite in direction to the first proximal moment.

25. The method of claim 22 wherein one of the first pressures is greater than the environmental pressure; and wherein the first distal moment is substantially the same direction as the first proximal moment.

26. The method of claim 22 further comprising the steps of: (i) positioning the device on a second pivot of a second holder, the second pivot being spaced apart from the first pivot; (ii) generating a second distal moment on the device near the second pivot by creating a pressure controlled, second distal zone between the second holder and the device that is at a second distal pressure; and (iii) generating a second proximal moment on the device near the second pivot by creating a pressure controlled, second proximal zone between the second holder and the device that is at a second proximal pressure; the second proximal zone being closer to the central axis than the second distal zone; wherein at least one of the second pressures is less than the environmental pressure.
